(19) United States
(12) Patent Application Publication
(10) Pub. No.: US 2026/0322071 A1
(43) Pub. Date: Oct. 15, 2026

(54) LIGHT SOURCE DEVICE, RANGING DEVICE, AND RANGING METHOD

(71) Applicant: SONY GROUP CORPORATION, TOKYO (JP)

(72) Inventors: KENJI TANAKA, TOKYO (JP); GEN YONEZAWA, TOKYO (JP)

(21) Appl. No.: 19/105,491

(22) PCT Filed: Aug. 18, 2023
(86) PCT No.: PCT/JP2023/029829

§ 371 Date: Feb. 21, 2025

(30) Foreign Application Priority Data
Aug. 31, 2022 (JP) 2022-138754

(51) Int. Cl. H01S 5/042; H01S 3/0941; H01S 3/113

(52) U.S. Cl. CPC H01S 5/042; H01S 3/0941; H01S 3/113

(57) ABSTRACT

[Problem] A light source device can be miniaturized and can vary peak power.

[Means of Solution] The light source device includes: a laminated semiconductor layer that includes an active layer that emits light of a first wavelength that is a wavelength that changes according to a driving condition, and a first reflection layer that is used for the first wavelength: a second reflection layer that is disposed on a first surface facing a light emission surface of the laminated semiconductor layer, and is used for a second wavelength; a third reflection layer that is disposed on a second surface disposed closer to a rear side of an optical axis than the first surface, and is used for the first wavelength; a laser medium that is disposed between the second reflection layer and the third reflection layer; a fourth reflection layer that is disposed on the second surface or is disposed closer to the rear side of the optical axis than the second surface and is used for the second wavelength; and a first resonator that resonates the light of the first wavelength between the first reflection layer and the third reflection layer, and an optical axis of the laminated semiconductor layer and an optical axis of the laser medium are arranged uniaxially.

### TECHNICAL FIELD

The present disclosure relates to a light source device, a ranging device, and a ranging method.

### BACKGROUND ART

A laser technique is applied to various fields such as microfabrication, medical, or ranging fields. Application of a short pulse laser technique in particular to a highly accurate machining technique or a highly efficient wavelength conversion technique is expected. A light source device that uses a Q switch among these techniques can obtain high peak power that exceeds kilowatt (kW) with a relatively simple configuration, and therefore is used in a wide application field. There has been proposed a light source device that is miniaturized and improves peak power by causing resonators of excitation light and oscillation light to overlap (see, for example, PTL 1 and 2).

In recent years in particular, a light source device is used as a light source of a laser ranging device Light Detection and Range (LiDAR). High peak power of a light source device can increase a ranging distance, and therefore there is demanded a light source device that can be miniaturized and has high peak power.

### CITATION LIST

### Patent Literature

### [PTL 1]

WO 21/106757

### [PTL 2]

JP 2015-138938A

### SUMMARY

### Technical Problem

When a light source device is used as a light source of a ranging distance, high peak power of the light source device can increase a ranging distance, so that it is possible to measure a distance to a more remote region. However, when a distance to a close distance region is measured, the high peak power as is may cause a problem in terms of laser safety. For example, a current injection type laser such as a semiconductor laser can easily change peak power by changing a driving method determined on the basis of a current value and an injection time. However, in a case where a light source device that uses a passive Q switch of a solid state laser is used, peak power is determined according to a Q value resulting from a structure of a resonator or characteristics of a laser medium or a saturable absorption material to be used, and it has been difficult to vary the peak power once the structure of the resonator is determined.

To solve the above problem, the present disclosure provides a light source device that can be miniaturized and can vary peak power using a passive Q switch of a solid state laser.

### Solution to Problem

In order to solve the above problem, the present disclosure provides a light source device that includes:
a laminated semiconductor layer that includes an active layer that emits light of a first wavelength that is a wavelength that changes according to a driving condition, and a first reflection layer that is used for the first wavelength;
a second reflection layer that is disposed on a first surface facing a light emission surface of the laminated semiconductor layer, and is used for a second wavelength;
a third reflection layer that is disposed on a second surface disposed closer to a rear side of an optical axis than the first surface, and is used for the first wavelength; a laser medium that is disposed between the second reflection layer and the third reflection layer;
a fourth reflection layer that is disposed on the second surface or is disposed closer to the rear side of the optical axis than the second surface and is used for the second wavelength; and
a first resonator that resonates the light of the first wavelength between the first reflection layer and the third reflection layer, and
an optical axis of the laminated semiconductor layer and an optical axis of the laser medium are arranged uniaxially.

The driving condition may include at least one of a driving current to be injected into the active layer, and a temperature of the active layer.

The active layer may emit light of one of at least two types of the first wavelengths whose wavelengths are respectively different according to the driving current, and the third reflection layer may have respectively different reflectances for the at least two types of first wavelengths.

The active layer may emit the light of the longer first wavelength as the driving current is larger, and
the third reflection layer may make the reflectance higher as the first wavelength is longer.

The active layer may emit the light of the longer first wavelength as the driving current is larger, and
the third reflection layer may make the reflectance lower as the first wavelength is longer.

The first wavelength may include a third wavelength that is emitted when a first driving current is caused to flow to the active layer, and a fourth wavelength that is emitted when a second driving current is caused to flow to the active layer, and the third reflection layer may have respectively different reflectances for the third wavelength and the fourth wavelength.

The third reflection layer has the higher reflectance for the fourth wavelength than the reflectance for the third wavelength, and
the laser medium may not excite the second wavelength for the third wavelength, and may excite the second wavelength for the fourth wavelength.

The third reflection layer may have the lower reflectance for the fourth wavelength than the reflectance for the third wavelength, and
the laser medium may not excite the second wavelength for the fourth wavelength, and may excite the second wavelength for the third wavelength.

The first driving current may be smaller than the second driving current, and the third wavelength may be shorter than the fourth wavelength.

The laminated semiconductor layer may include a plurality of first regions that emit light of the respectively different first wavelengths, and
the third reflection layer may include a plurality of the second regions that are provided to meet the plurality of first regions, and have respectively different reflectances for the first wavelengths.

The laminated semiconductor layer may include a plurality of first regions that emit light of the third wavelength or the fourth wavelength, and
the third reflection layer may include a plurality of second regions that are provided to meet the plurality of the first regions, and have respectively different reflectances for the third wavelength and the fourth wavelength.

The laminated semiconductor layer may intermittently emit the light of the first wavelength.

The light source device may further include
a second resonator that resonates light of the second wavelength between the second reflection layer and the fourth reflection layer.

The light source device may further include a saturable absorber that includes the fourth reflection layer, and
the optical axis of the laminated semiconductor layer, the optical axis of the laser medium, and an optical axis of the saturable absorber are arranged uniaxially.

The light of the second wavelength may have peak power higher than peak power of the light of the first wavelength.

The fourth reflection layer may emit Q switch pulse wave light of the second wavelength.

Furthermore, the present disclosure provides a ranging device that includes: a light source device that can switch a wavelength and emit light;
a light reception unit; and
a distance measurement unit that, when a light emission signal of the light source device is reflected by a target and received by the light reception unit, measures a distance to the target based on the light emission signal and a light reception signal of the light reception unit,
the light source device includes
a laminated semiconductor layer that includes an active layer that emits light of a first wavelength that is a wavelength that changes according to a driving condition, and a first reflection layer that is used for the first wavelength,
a second reflection layer that is disposed on a first surface facing a light emission surface of the laminated semiconductor layer, and is used for a second wavelength,
a third reflection layer that is disposed on a second surface disposed closer to a rear side of an optical axis than the first surface, and is used for the first wavelength,
a laser medium that is disposed between the second reflection layer and the third reflection layer,
a fourth reflection layer that is disposed on the second surface or is disposed closer to the rear side of the optical axis than the second surface and is used for the second wavelength,
a first resonator that resonates the light of the first wavelength between the first reflection layer and the third reflection layer, and
a second resonator that resonates light of the second wavelength between the second reflection layer and the fourth reflection layer, and
an optical axis of the laminated semiconductor layer and an optical axis of the laser medium are arranged uniaxially.

The light source device may further include a driving unit that controls the driving condition according to the distance to the target.

The driving unit may switch and control peak power of the light emission signal emitted from the light source device according to the distance to the target.

Furthermore, the present disclosure provides a ranging method that includes when a light emission signal of a light source device that can switch a wavelength and emit light is reflected by a target and received by a light reception unit, measuring a distance to the target based on the light emission signal and a light reception signal of the light reception unit,
the light source device is formed by laminating
a laminated semiconductor layer that includes an active layer that emits light of a first wavelength that is a wavelength that changes according to a driving condition, and a first reflection layer that is used for the first wavelength,
a second reflection layer that is disposed on a first surface facing a light emission surface of the laminated semiconductor layer, and is used for a second wavelength,
a third reflection layer that is disposed on a second surface disposed closer to a rear side of an optical axis than the first surface, and is used for the first wavelength, a laser medium that is disposed between the second reflection layer and the third reflection layer,
a fourth reflection layer that is disposed on the second surface or is disposed closer to the rear side of the optical axis than the second surface and is used for the second wavelength,
a first resonator that resonates the light of the first wavelength between the first reflection layer and the third reflection layer, and
a second resonator that resonates light of the second wavelength between the second reflection layer and the fourth reflection layer, and
an optical axis of the laminated semiconductor layer and an optical axis of the laser medium are arranged uniaxially.

### BRIEF DESCRIPTION OF DRAWINGS

FIG. 1 is a schematic view illustrating a configuration of a light source device according to a first embodiment.

FIG. 2 is a schematic view illustrating a configuration of an excitation light source and a support body according to the first embodiment.

FIG. 3A is a diagram illustrating how a first wavelength emitted by an active layer changes according to a driving current.

FIG. 3B is a diagram illustrating how the first wavelength emitted by the active layer changes according to a temperature.

FIG. 4A is a diagram illustrating how the reflectance of a third reflection layer changes according to the first wavelength.

FIG. 4B shows a graph obtained by extracting sections Aa to Ad in a graph in FIG. 4A.

FIG. 4C shows a graph obtained by extracting sections Ac to Af in the graph in FIG. 4A.

FIG. 5A is a diagram illustrating a laser operation of the light source device in a case where excitation light transmits through the third reflection layer.

FIG. 5B is a diagram illustrating the laser operation of the light source device in a case where excitation light is reflected by the third reflection layer.

FIG. 6 is a schematic view illustrating a configuration of the light source device according to a second embodiment.

FIG. 7A is a diagram illustrating checkered pattern light emission of the light source device according to the second embodiment.

FIG. 7B is a diagram illustrating line & space pattern light emission of the light source device according to the second embodiment.

FIG. 8A is a diagram illustrating a pulse current to be applied to the active layer according to a third embodiment.

FIG. 8B is a diagram illustrating output of first oscillation light L1 according to the third embodiment.

FIG. 8C is a diagram illustrating output of second oscillation light L2.

FIG. 9 is a diagram illustrating a configuration example of a ranging device as an implementation example of the light source device according to a fourth embodiment.

FIG. 10A is a diagram illustrating an emitting operation of laser light of the light source device in a case where a subject is at a close distance from the ranging device.

FIG. 10B is a diagram illustrating the emitting operation of the laser light of the light source device in a case where the subject is at a remote distance from the ranging device.

FIG. 11 is a block diagram illustrating an example of a schematic configuration of a vehicle control system.

FIG. 12 is an explanatory diagram illustrating an example of installation positions of vehicle exterior information detecting units and imaging units.

### DESCRIPTION OF EMBODIMENTS

Hereinafter, embodiments of a light source device, a ranging device, and a ranging method will be described with reference to the drawings. Hereinafter, although main components of the light source device, the ranging device, and the ranging method will be mainly described, the light source device, the ranging device, and the ranging method may include components or functions that are not illustrated or described. The following description does not exclude the components or the functions that are not illustrated or described.

### First Embodiment

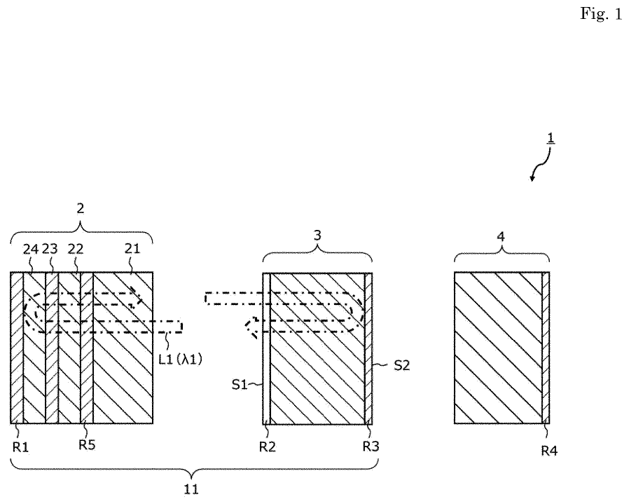

FIG. 1 is a schematic view illustrating a configuration of a light source device 1 according to the first embodiment. The light source device 1 is used as, for example, a medical laser or a ranging device light source to be described later. The light source device 1 includes an excitation light source (laminated semiconductor layer) 2 and a laser medium 3. Furthermore, the light source device 1 may include a saturable absorber 4.

The excitation light source 2 emits first oscillation light L1 for exciting the laser medium 3. The excitation light source 2 includes a semiconductor layer of a laminated structure formed by laminating a substrate 21, a fifth reflection layer R5, a clad layer 22, an active layer 23, a clad layer 24, and a first reflection layer R1 in order.

Although the excitation light source 2 in FIG. 1 employs a bottom emission type configuration that emits the first oscillation light L1 of a Continuous Wave (CW) from the substrate 21, yet may also employ a top emission type configuration that emits CW excitation light from the first reflection layer R1 side.

The substrate 21 is, for example, an n-GaAs substrate. The n-GaAs substrate absorbs a certain rate of the first oscillation light L1 that is an excitation wavelength of the excitation light source 2, and therefore is desirably made as thin as possible to suppress absorption. On the other hand, the n-GaAs substrate desirably has such a thickness that mechanical strength at a time when, for example, the n-GaAs substrate is bonded to other members later can be maintained.

The active layer 23 performs surface light emission of the first oscillation light L1. The clad layers 22 and 24 are, for example, AlGaAs clad layers. The first reflection layer R1 reflects the first oscillation light L1. The fifth reflection layer R5 has a certain transmittance with respect to the first oscillation light L1. For example, Distributed Bragg Reflectors (DBRs) that enable electrical conduction are used for the first reflection layer R1 and the fifth reflection layer R5. The current (driving current) is injected from the outside through the first reflection layer R1 and the fifth reflection layer R5 from an unillustrated electrode in FIG. 1, recombination and light emission occur in a quantum well in the active layer 23, and the first oscillation light L1 is emitted.

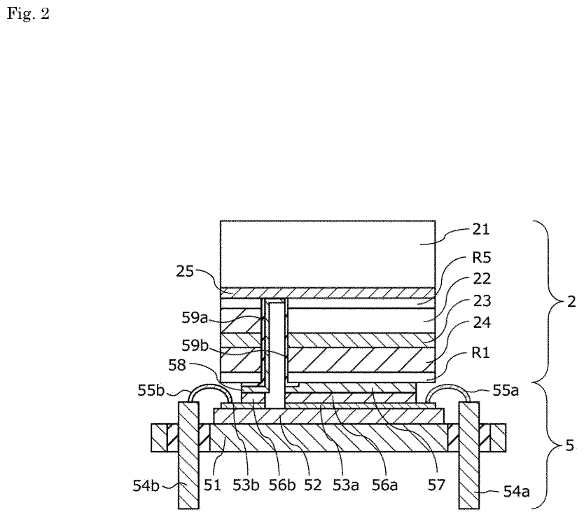

FIG. 2 is a cross-sectional view illustrating a support structure of the excitation light source 2 according to the first embodiment. Although not illustrated in FIG. 2, the laser medium 3 illustrated in FIG. 1 may be disposed on the substrate 21 in FIG. 2, and the saturable absorber 4 may be disposed thereon.

The excitation light source 2 includes an n-type contact layer 25 in addition to the laminated structure illustrated in FIG. 1. The contact layer 25 is laminated between the substrate 21 and the fifth reflection layer R5. The contact layer 25 conducts with a conductive layer 58 that covers sidewalls of the fifth reflection layer R5, the clad layer 22, the active layer 23, the clad layer 24, and the first reflection layer R1. The conductive layer 58 is an n-type metal layer, and insulation layers 59a and 59b are disposed around this conductive layer 58.

A support body 5 employs a configuration where a submount member 52 is disposed on a mount member 51. Wiring layers 53a and 53b are isolated from each other and disposed on the submount member 52. The wiring layer 53a conducts with a conductive layer 57 laminated on the first reflection layer R1 with solder layers 56a and 56b interposed therebetween. The conductive layer 57 is a p-type metal layer.

To the mount member 51, pins 54a and 54b are attached. The pins 54a and 54b are disposed penetrating the mount member 51, and are connected to an unillustrated driving power supply. The pins 54a and 54b are connected with the wiring layers 53a and 53b, respectively, by wires 55a and 55b. An application voltage of the pin 54a is applied to the first reflection layer R1 via the wire 55a, the wiring layer 53a, the solder layer 56a, and the conductive layer 57. Furthermore, an application voltage of the pin 54b is applied to the contact layer 25 via the wire 55b, the wiring layer 53b, the solder layer 56b, and the conductive layer 58.

Thus, a driving current matching a potential difference between the voltage applied to the first reflection layer R1 and the voltage applied to the contact layer 25 is injected into the active layer 23.

In this description, the wavelength of the first oscillation light L1 will be referred to as a first wavelength λ1. The first wavelength λ1 changes depending on a semiconductor material in the excitation light source 2. Furthermore, the first wavelength λ1 also changes depending on a driving condition. The driving condition depends on, for example, the temperature of the active layer 23 or the above-described driving current.

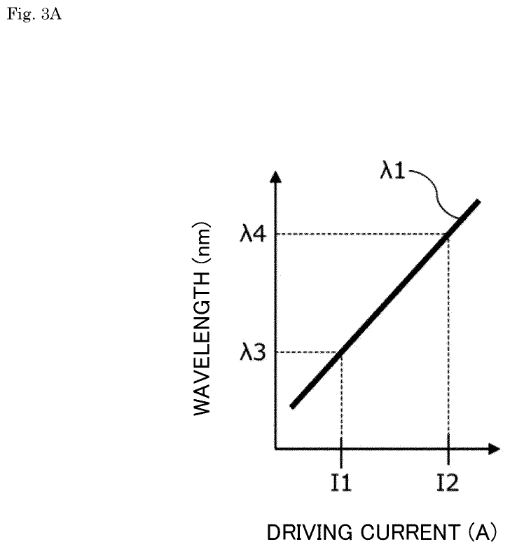

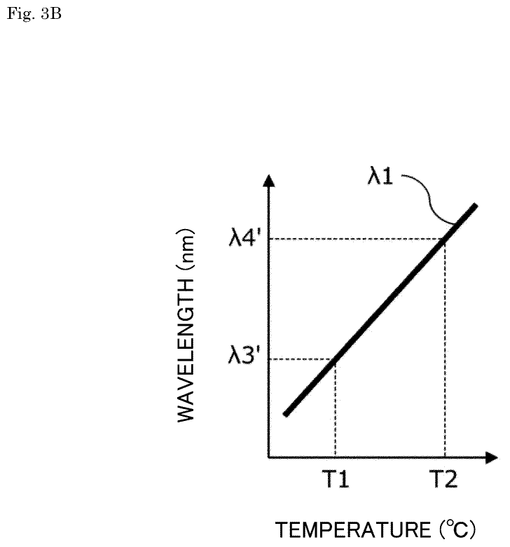

FIG. 3A is a diagram illustrating how the first wavelength λ1 emitted by the active layer 23 changes according to the driving current. The horizontal axis indicates a current amount of the driving current, and the vertical axis indicates the wavelength of the first oscillation light L1. As illustrated in FIG. 3A, the active layer 23 emits the first oscillation light L1 of a longer wavelength as the driving current is larger.

In this description, a third wavelength λ3 that is emitted when a first driving current I1 is caused to flow, and a fourth wavelength λ4 that is emitted when a second driving current I2 is caused to flow will be collectively referred to as the first wavelength λ1. Note that the first driving current I1 is smaller than the second driving current 12. In this case, the third wavelength λ3 is shorter than the fourth wavelength λ4.

FIG. 3B is a diagram illustrating how the first wavelength λ1 emitted by the active layer 23 changes according to a temperature. The horizontal axis indicates the temperature of the active layer 23, and the vertical axis indicates the magnitude of the wavelength. As illustrated in FIG. 3B, the active layer 23 emits the first oscillation light L1 of a longer wavelength as the temperature is higher. In this description, a third wavelength λ3′ that is emitted at a first temperature T1, and a fourth wavelength λ4′ that is emitted at a second temperature T2 will be collectively referred to as the first wavelength λ1.

As illustrated in FIGS. 3A and 3B, the active layer 23 can switch and emit at least two types of the first oscillation light L1 having respectively different wavelengths by controlling the driving current or the temperature.

The fifth reflection layer R5 is disposed on, for example, the substrate 21. For example, the fifth reflection layer R5 includes a multilayer reflection film made of Alz1Ga1−z1As/Alz2Ga1−z2As (0≤z1≤z2≤1)doped with an n-type dopant (e.g., silicon). The fifth reflection layer R5 will be also referred to as an n-DBR.

The active layer 23 includes, for example, a multiple quantum well layer formed by laminating an Alx1Iny1Ga1−x1−y1As layer and an Alx3Iny3Ga1−x3−y3As layer.

The first reflection layer R1 includes, for example, a multilayer reflection film made of Alz3Ga1−z3As/Alz4Ga1−z4As (0≤z3≤z4≤1) doped with a p-type dopant (e.g., carbon). The first reflection layer R1 will be also referred to as a p-DBR.

Each semiconductor layer (the fifth reflection layer R5, the clad layer 22, the active layer 23, the clad layer 24, and the first reflection layer R1) in the excitation light source 2 that is an excitation light resonator can be formed using a crystal growth method such as a Metal Organic Chemical Vapor Deposition (MOCVD) method or a Molecular Beam Epitaxity (MBE) method. Furthermore, it is possible to perform driving by driving current injection after a process such as mesa etching for element isolation, formation of an insulating film, deposition of an electrode film, and the like after crystal growth.

The excitation light source 2 only needs to be a member that emits excitation light that can excite the laser medium 3, and does not necessarily need to be a semiconductor laser element. Furthermore, a material used for the excitation light source 2 may be a crystalline material or may be an amorphous material such as ceramics. Furthermore, the excitation light source 2 only needs to be able to cause the first oscillation light L1 to enter the laser medium 3, and may not include an optical system such as a lens.

The laser medium 3 is disposed on a side opposite to the fifth reflection layer R5 of the substrate 21 of the excitation light source 2, that is, on a rear side of an optical axis. The laser medium 3 includes a second reflection layer R2 and a third reflection layer R3.

The second reflection layer R2 is disposed on a first surface S1 facing a light emission surface of the excitation light source 2. The third reflection layer R3 is disposed on a second surface S2 closer to a rear side of the optical axis than the first surface S1. The laser medium 3 is disposed between the second reflection layer R2 and the third reflection layer R3.

The laser medium 3 emits second oscillation light L2 when excited by the first oscillation light L1. For example, the laser medium 3 is disposed so as to face the saturable absorber 4. Furthermore, the optical axis of the excitation light source 2 and the optical axis of the laser medium 3 are aligned uniaxially. Note that the wavelength of the second oscillation light L2 will be referred to as a second wavelength λ2 in this description.

The laser medium 3 contains, for example, Yttrium Aluminum Garnet (YAG) crystal Yb: YAG doped with Ytterbium (Yb).

The laser medium 3 is not limited to, for example, Yb: YAG, and, for example, at least one material of Nd:YAG, Nd:YVO4, Nd:YLF, Nd:glass, Yb:YAG, Yb:YLF, Yb:FAP, Yb:SFAP, Yb:YVO, Yb:glass, Yb:KYW, Yb:BCBF, Yb:YCOB, Yb:GdCOB, and Yb:YAB can be used as the laser medium 3.

Furthermore, the laser medium 3 may be the four-level system solid state laser medium, or may be a three-level system solid state laser medium. In this regard, since each crystal has a different appropriate excitation wavelength, it is necessary to select a material of the laser medium 3 according to the first wavelength λ1.

A surface on a laser output side (third reflection layer R3) in the laser medium 3 may be provided with a reflection layer (e.g., dielectric multilayer film) that reflects excitation light.

The second reflection layer R2 disposed on the excitation light source 2 side among a pair of the second reflection layer R2 and the third reflection layer R3 allows, for example, the first oscillation light L1 of the first wavelength λ1 emitted from the excitation light source 2 to transmit therethrough, and reflects at a predetermined reflectance the second oscillation light L2 of the second wavelength λ2 emitted from the laser medium 3.

On the other hand, the third reflection layer R3 equipped to an opposite side of the excitation light source 2 allows, for example, the second oscillation light L2 of the second wavelength λ2 emitted from the laser medium 3 to transmit therethrough.

Furthermore, the third reflection layer R3 has respectively different reflectances for at least two types of the first oscillation light L1 having respectively different wavelengths depending on the above-described driving current.

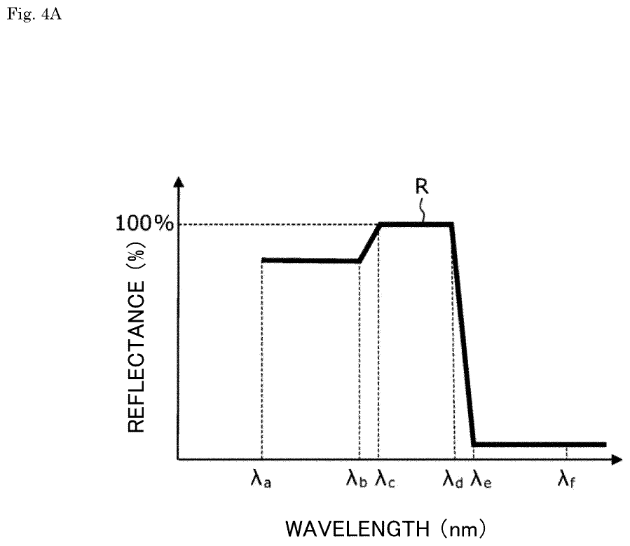

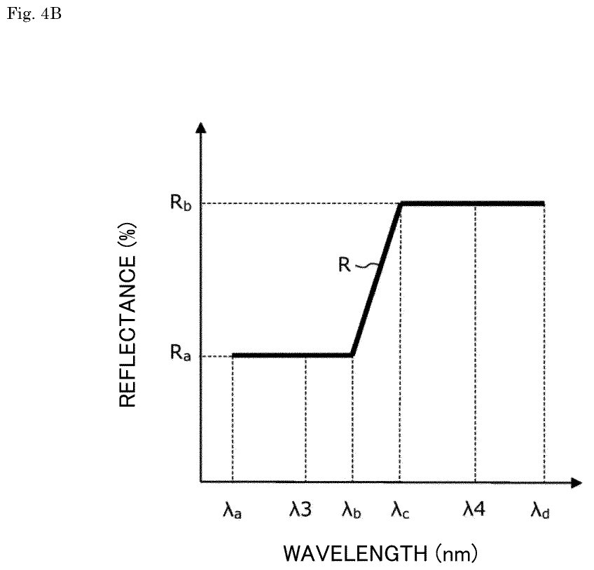

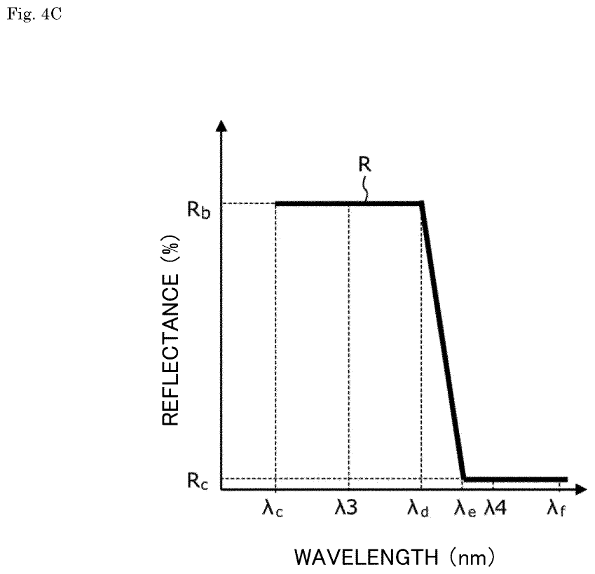

FIG. 4A is a diagram illustrating how a reflectance R of the third reflection layer R3 changes according to the wavelength of the first oscillation light L1. The horizontal axis indicates the wavelength of the first oscillation light L1, and the vertical axis indicates the reflectance R of the third reflection layer R3. In FIG. 4A, the reflectance R is approximately 100% at maximum.

In FIG. 4A, the wavelength increases in order of wavelength λa<λb<λc<λd<λe<λf. The reflectance R is constant at the wavelengths λa to λb. The reflectance R increases at the wavelengths λb to λc. The reflectance R is constant at the wavelengths λc to λd, and the reflectance R at this time is maximum. The reflectance R decreases at the wavelengths λd to λe. The reflectance R is constant at the wavelengths λe to f, and the reflectance R at this time is minimum.

FIG. 4B is a diagram that enlarges a section of the wavelengths λa to λd in the graph in FIG. 4A. As illustrated in FIG. 4B, the above-described third wavelength λ3 may be between the wavelengths λa and λb. Furthermore, the fourth wavelength λ4 may be between the wavelengths λc and λd. In this case, the third reflection layer R3 has a reflectance Ra for the third wavelength λ3. Furthermore, the third reflection layer R3 has a higher reflectance Rb for the fourth wavelength λ4 than the reflectance Ra.

The reflectance Rb may be approximately 100%. In this case, the third reflection layer R3 totally reflects the first oscillation light L1 when the first oscillation light L1 has the fourth wavelength λ4. On the other hand, when the first oscillation light L1 has the third wavelength λ3, the third reflection layer R3 allows light of a certain amount to transmit therethrough.

FIG. 4C is a diagram that enlarges a section of the wavelengths λc to λf in the graph in FIG. 4A. As illustrated in FIG. 4C, the above-described third wavelength λ3 may be between the wavelengths λc and λd. Furthermore, the fourth wavelength λ4 may be between the wavelengths λe and λf. In this case, the third reflection layer R3 has the reflectance Rb for the third wavelength λ3. Furthermore, the third reflection layer R3 has a lower reflectance Rc for the fourth wavelength λ4 than the reflectance Rb.

Similarly to FIG. 4B, when the reflectance Rb is approximately 100%, the third reflection layer R3 totally reflects the first oscillation light L1 of the third reflection layer λ3. On the other hand, the third reflection layer R3 allows the first oscillation light L1 of the fourth wavelength λ4 to transmit therethrough to some degree.

For the second reflection layer R2 and the third reflection layer R3 in FIG. 1, for example, a dielectric multilayer film formed by alternately laminating a layer made of a high refractive index material and a layer made of a low refractive index material is used. The thickness of the dielectric multilayer film is, for example, one fourth of the wavelength of the first oscillation light L1, and a total number is several layers to several hundreds of layers. As the high refractive index material of the dielectric multilayer film, a material such as Al2O3, HfO2, TiO2, ZrO2, Ta2O5, Nb2O5, and ZnO2 having the refractive index of 1.6 to 2.5 is used, and, as the low refractive index material, a material such as SiO2, Al2O3, and MgF2 having the refractive index of 1.2 to 1.6 is used. Examples of a method for forming the dielectric multilayer film include the Chemical Vapor Deposition (CVD) method, the reactive sputtering method, the Radical Assisted Sputtering (RAS) method, the vacuum deposition method, and the ion assisted deposition method. Furthermore, such a reflection film may be formed to form both principal surfaces of an optical filter. The layer structures, the material, and the film formation method of the second reflection layer R2 and the third reflection layer R3 are not limited to the above example.

The excitation light source 2 and the laser medium 3 constitute a first resonator 11. Inside of the first resonator 11, three reflection layers (the first reflection layer R1, the fifth reflection layer R5, and the third reflection layer R3) are provided. Hence, the first resonator 11 has a coupled cavity structure.

The light source device 1 in FIG. 1 may include the saturable absorber 4 that is disposed so as to face the third reflection layer R3 of the laser medium 3. The saturable absorber 4 includes a fourth reflection layer R4. An optical axis of the saturable absorber 4 is aligned uniaxially with the optical axis of the excitation light source 2 and the optical axis of the laser medium 3.

The saturable absorber 4 is, for example, a member that is a made of Cr:YAG, absorbs light of a predetermined wavelength, and has a property that a light absorption rate becomes low due to saturation of light absorption. The saturable absorber 4 absorbs, for example, the second oscillation light L2, and allows the first oscillation light L1 to transmit therethrough.

Thus, the saturable absorber 4 functions as a passive Q switch for the second oscillation light L2. That is, in a case where the light source device 1 outputs light of the second wavelength λ2, the light source device 1 is a passive Q switch pulse laser device.

When, for example, the second oscillation light L2 emitted from the laser medium 3 enters the saturable absorber 4, the saturable absorber 4 absorbs this second oscillation light L2, and, as an absorption rate increases, the transmittance of the saturable absorber 4 increases. Then, when the electron density of an excitation level increases, and the excitation level is satisfied, the saturable absorber 4 becomes transparent, a Q value of an optical resonator increases, and laser oscillation occurs.

The fourth reflection layer R4 is a partial reflection layer that has a function of an output coupler. The fourth reflection layer R4 is disposed closer to the rear side of the optical axis than the second surface S2. More specifically, the fourth reflection layer R4 is disposed along a light emission surface side of the saturable absorber 4. Note that, as described above, the light source device 1 may not include the saturable absorber 4. In a case where the light source device 1 does not include the saturable absorber 4, the fourth reflection layer R4 may be disposed on the second surface S2. In this case, the second oscillation light L2 that is a continuous wave is emitted from the fourth reflection layer R4, yet peak power of the second oscillation light L2 is smaller than that of Q switch light emitted from the saturable absorber 4.

The excitation light source 2, the laser medium 3, and the saturable absorber 4 in the light source device 1 may be integrally bonded. Furthermore, a spacer, a polarization control element, a heat exhaust member, or the like may be disposed between the excitation light source 2 and the laser medium 3 or between the laser medium 3 and the saturable absorber 4.

The passive Q switch pulse laser device is used as, for example, a light emission device for a ranging device. At a time of ranging, for example, the passive Q switch pulse laser device irradiates a target object with pulsed light, and the ranging device receives the light reflected from the object and thereby measures a distance to the object.

For the ranging device, the pulsed light emitted from the passive Q switch pulse laser device is suitable to be radiated to an object at a remote distance. On the other hand, when an object at a close distance is irradiated with pulsed light, the pulsed light causes a problem in terms of laser safety. When a ranging target object is at a close distance, it is desirable to irradiate the ranging target object with light of low peak power compared to a case of a remote distance in terms of laser safety.

As described above, although it is desirable for the ranging device to switch peak power of laser light according to a distance to an object for which ranging is performed, it is not easy for the existing passive Q switch pulse laser device to switch peak power. The light source device 1 according to the present embodiment to be described below has a feature that the light source device 1 can switch peak power of laser light to be emitted.

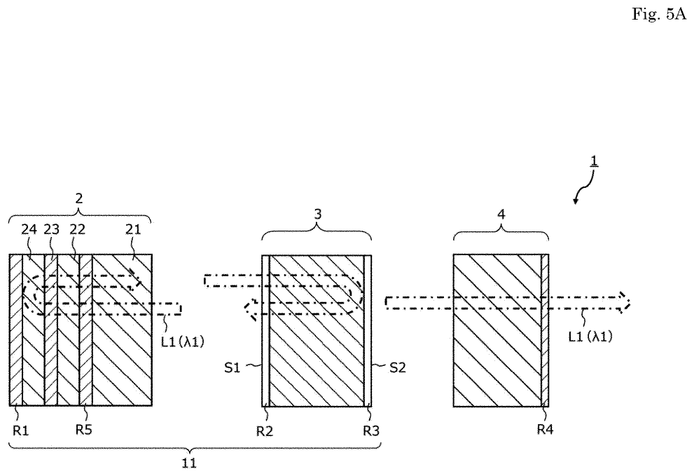

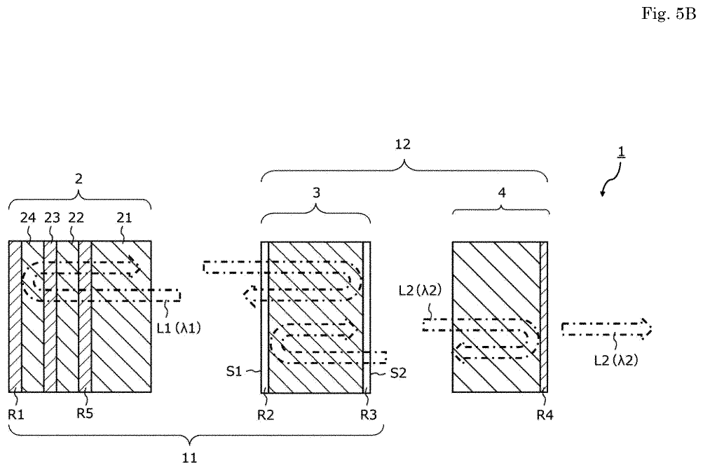

FIGS. 5A and 5B are diagrams for describing an operation of the light source device 1 according to the present embodiment. A driving current is injected into the active layer 23 via an unillustrated electrode of the excitation light source 2 to perform surface light emission of the first oscillation light L1 from the active layer 23.

By controlling the driving current to be injected into the active layer 23 or the temperature, it is possible to cause the active layer 23 to emit the first oscillation light L1 of the third wavelength λ3 between the wavelengths λa and λb illustrated in FIG. 4B. In this case, the first oscillation light L1 transmits through the third reflection layer R3. Accordingly, the laser medium 3 cannot sufficiently absorb the first oscillation light L1, and therefore cannot excite the second oscillation light L2.

The above description also applies to a case where the active layer 23 is caused to emit the first oscillation light L1 of the fourth wavelength λ4 between the wavelengths λe and λf in FIG. 4C. Similarly, in this case, too, the first oscillation light L1 transmits through the third reflection layer R3, and therefore the laser medium 3 does not excite the second oscillation light L2.

FIG. 5A illustrates as broken lines how the first oscillation light L1 transmits through the third reflection layer R3. In this case, the first resonator 11 resonates the first oscillation light L1 between the first reflection layer R1 of the excitation light source 2 and the third reflection layer R3 of the solid state laser medium 3, and emits the first oscillation light L1 from the third reflection layer R3. The first oscillation light L1 having transmitted through the third reflection layer R3 transmits through the saturable absorber 4, further transmits through the fourth reflection layer R4, and is emitted from the light source device 1. In this case, the laser medium 3 and the saturable absorber 4 do not perform a Q switch operation.

In FIG. 5A, the light source device 1 functions as a laser device that emits the first oscillation light L1 that is a continuous wave. In this case, it is possible to vary peak power by, for example, Pulse Width Modulation (PWM) driving to be described later.

On the other hand, by controlling the driving current to be given to the active layer 23 or the temperature, it is possible to cause the active layer 23 to emit the first oscillation light L1 of the fourth wavelength λ4 between the wavelengths λc and λd in FIG. 4B. In this case, the third reflection layer R3 reflects the first oscillation light L1 at the reflectance Rb.

Hence, the first resonator 11 traps power of the first oscillation light L1 inside between the first reflection layer R1 and the third reflection layer R3.

Consequently, the laser medium 3 can sufficiently absorb the first oscillation light L1, so that the laser medium 3 is excited and the second oscillation light L2 of the second wavelength is generated. That is, the first oscillation light L1 functions as excitation light.

The same also applies to a case where the active layer 23 is caused to emit the first oscillation light L1 of the third wavelength λ3 between the wavelengths λc and λd in FIG. 4C. In this case, the first oscillation light L1 is reflected by the third reflection layer R3 at the reflectance Rb, and is trapped in the first resonator 11, so that the laser medium 3 excites the second oscillation light L2.

FIG. 5B illustrates as broken lines how the first oscillation light L1 is reflected by the third reflection layer R3. In a case of FIG. 5B, the laser medium 3 and the saturable absorber 4 constitute a second resonator 12. That is, the light source device 1 in FIG. 5B has a structure formed by integrating the first resonator 11 and the second resonator 12. Furthermore, the first resonator 11 and the second resonator 12 have structures that share a member (the laser medium 3 in the example in FIG. 5B) between the second reflection layer R2 and the third reflection layer R3.

At a first stage at which the laser medium 3 emits light, the second oscillation light L2 is absorbed by the saturable absorber 4, and the saturable absorber 4 in the second resonator 12 does not cause light emission from the fourth reflection layer R4 on an emission surface side of the saturable absorber 4.

Subsequently, when the first oscillation light L1 is absorbed by the laser medium 3 and enters an excited state, an output of the second oscillation light L2 increases and, when the output exceeds a certain threshold, a light absorption rate of the saturable absorber 4 rapidly lowers.

Thus, the second resonator 12 resonates the second oscillation light L2 between the second reflection layer R2 of the laser medium 3 and the fourth reflection layer R4 of the saturable absorber 4, and the second oscillation light L2 is emitted as a Q switch pulse wave from the reflection layer R4 side.

The second oscillation light L2 in FIG. 5B performs a passive Q switch operation, and therefore has higher peak power than that of the first oscillation light L1 in FIG. 5A.

As described above, by controlling the driving current or the temperature, the active layer 23 can emit the first oscillation light L1 of the third wavelength λ3 and the fourth wavelength λ4 of arbitrary wavelengths. When, for example, the third wavelength λ3 is between the wavelengths λa and λb in FIG. 4B and the fourth wavelength λ4 is between the wavelengths λc and λd, the third reflection layer R3 has the higher reflectance for the fourth wavelength λ4 than the reflectance for the third wavelength λ3. Consequently, the laser medium 3 does not excite the second oscillation light L2 for the first oscillation light L1 of the third wavelength λ3, and excites the second oscillation light L2 for the first oscillation light L1 of the fourth wavelength λ4.

On the other hand, when the third wavelength λ3 is between the wavelengths λc and λd in FIG. 4C and the fourth wavelength λ4 is between the wavelengths λe and λf, the third reflection layer R3 has the lower reflectance for the fourth wavelength λ4 than the reflectance for the third wavelength λ3.

Consequently, the laser medium 3 does not excite the second oscillation light L2 for the first oscillation light L1 of the fourth wavelength λ4, and excites the second oscillation light L2 for the first oscillation light L1 of the third wavelength λ3.

Note that, unless otherwise specified in particular in the following description, a case where the third wavelength λ3 is between the wavelengths λa and λb in FIG. 4B and the fourth wavelength λ4 is between the wavelengths λc and λd (i.e., a case where, when the first driving current I1 is injected into the active layer 23, the light source device 1 emits the first oscillation light L1, and, when the second driving current 12 is injected into the active layer 23, the light source device 1 emits the second oscillation light L2) will be described.

Thus, according to the first embodiment, the active layer 23 can emit at least two types of the first oscillation light L1 having the respectively different wavelengths according to the driving current. Furthermore, the third reflection layer R3 has the respectively difference reflectances for the respectively different wavelengths of the first oscillation light L1. Consequently, it is possible to switch whether to cause the first oscillation light L1 to transmit through the third reflection layer R3 or to be reflected by the third reflection layer R3 according to the driving current to be injected into the active layer 23.

Since, when the first oscillation light L1 has the third wavelength λ3, the laser medium 3 does not excite the second oscillation light L2, the light source device 1 emits the first oscillation light L1 having relatively low peak power. Since, when the first oscillation light L1 has the fourth wavelength λ4, the laser medium 3 excites the second oscillation light L2, the light source device 1 emits the second oscillation light L2 of the Q switch pulse wave. Consequently, by switching the driving current to be injected into the active layer 23 according to a distance to an object when, for example, ranging is performed, it is possible to switch and emit the first oscillation light L1 or the second oscillation light L2 having different peak power.

For example, to control peak power, the light source device 1 according to the present disclosure can be implemented by a simple configuration compared to a configuration where a part such as an optical element is externally added or a configuration where mechanism driving is added. Consequently, it is possible to reduce manufacturing cost, and achieve miniaturization.

### Second Embodiment

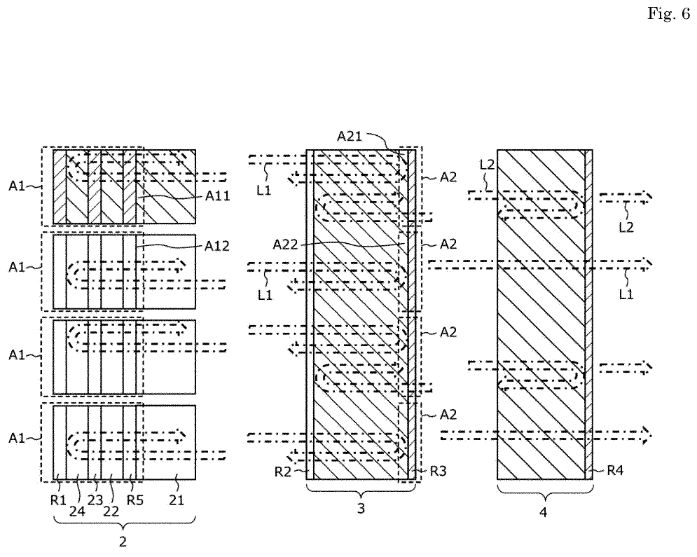

The light source device 1 according to the second embodiment has a feature that the light source device 1 has an array pattern structure. FIG. 6 is a cross-sectional view illustrating a configuration of the light source device 1 according to the second embodiment. The excitation light source 2 includes a plurality of first regions A1 that emit the first oscillation light L1. Furthermore, the third reflection layer R3 includes second regions A2 meeting the first regions A1.

The first region A1 is divided into a plurality of sub regions, and each sub region has a different driving condition of the active layer 23. In this case, two neighboring sub regions in the first region A1 emit the first oscillation light L1 having the respectively different first wavelengths λ1. Furthermore, the second region A2 is also divided into a plurality of sub regions. Two neighboring sub regions in the second region A2 have reflectances matching the wavelengths of the first oscillation light L1 emitted by the corresponding sub regions in the first region A1.

For example, in an example in FIG. 6, the first region A1 includes a sub region A11 that emits the first oscillation light L1 of the third wavelength λ3, and a sub region A12 that emits the first oscillation light L1 of the fourth wavelength λ4. The second region A2 includes a sub region A21 in which the first oscillation light L1 from the sub region A11 enters, and a sub region A22 in which the first oscillation light L1 from the sub region A12 enters.

The sub region A21 in the second region A2 has the reflectance Ra for the third wavelength λ3. Furthermore, the sub region A22 in the second region A2 has the reflectance Rb for the fourth wavelength λ4.

The fourth reflection layer R4 emits each of the first oscillation light L1 of low peak power and the second oscillation light L2 of high peak power.

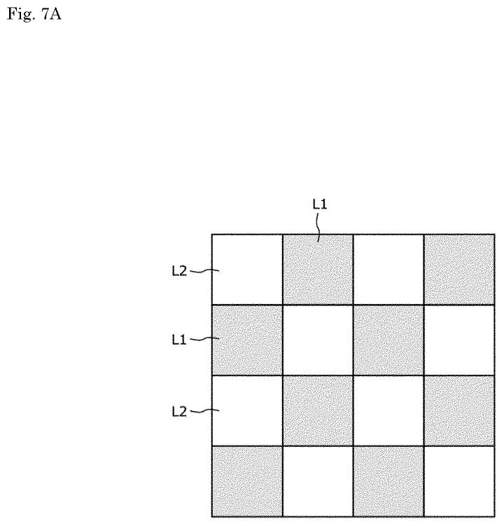

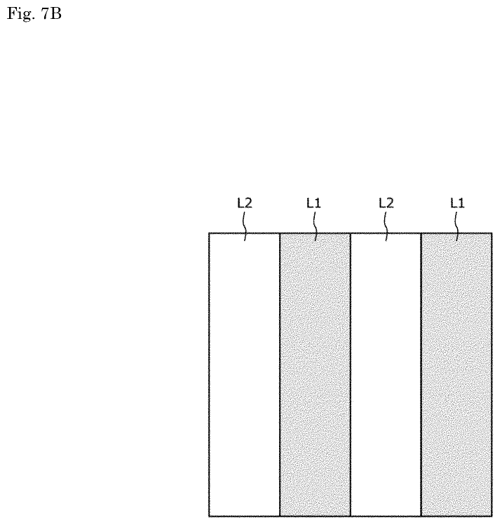

Sizes, the numbers of, and arrangement directions of the arranged sub regions A11 and A12 in the first region A1 are arbitrary. FIG. 7A is a diagram illustrating checkered pattern light emission of the light source device 1 according to the second embodiment. By arranging the sub regions A11 and A12 in the checkered pattern, it is possible to emit the first oscillation light L1 and the second oscillation light L2 in the checkered pattern as illustrated in FIG. 7A. FIG. 7B is a diagram illustrating line & space pattern light emission of the light source device 1 according to the second embodiment. By arranging the sub regions A11 and A12 per row or per column, it is possible to emit the first oscillation light L1 and the second oscillation light L2 in the line & space pattern as illustrated in FIG. 7B.

Thus, according to the second embodiment, the light source device 1 can simultaneously emit a plurality of the first reflection light L1 of different peak power. Consequently, for example, it is possible to measure a close distance and measure a remote distance at the same timing.

### Third Embodiment

The light source device 1 according to the first embodiment switches whether to emit the first oscillation light L1 of the continuous wave or to emit the second oscillation light L2 of the Q switch pulse wave by switching the driving current to be injected into the active layer 23. The first oscillation light L1 can be converted into pulse light similarly to the second oscillation light L2. According to the third embodiment, the driving current to be injected into the active layer 23 is converted into a pulse current to convert the first oscillation light L1 into pulse light.

Consequently, the light source device 1 according to the third embodiment can be used as a pulse light source that can switch between the first wavelength Al and the second wavelength λ2.

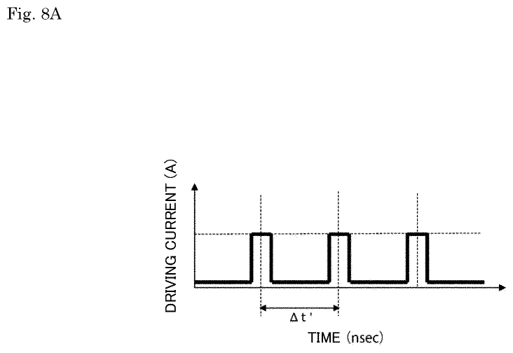

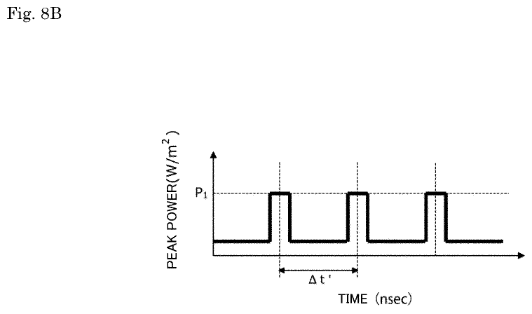

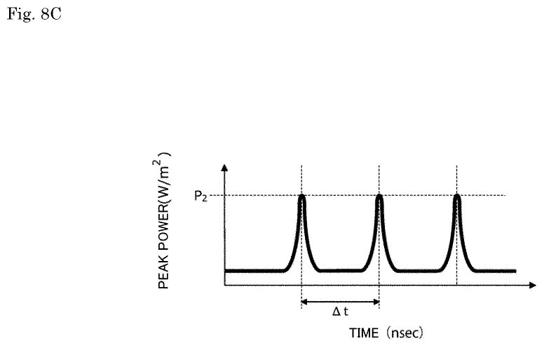

More specifically, in the third embodiment, the first driving current I1 to be injected into the active layer 23 is a pulse current. FIG. 8A is a diagram illustrating a pulse current waveform to be injected into the active layer 23. The horizontal axis indicates a time, and the vertical axis indicates the magnitude of a driving current. In the active layer 23, the first driving current I1 that is the pulse current is injected per predetermined time interval At'. By performing PWM control on a pulse width and a pulse interval of the pulse current, it is possible to arbitrarily adjust the peak power of the first oscillation light L1 of the third wavelength λ3.

The excitation light source 2 according to the third embodiment intermittently emits the first oscillation light L1 of the first wavelength λ1 according to the pulse current in FIG. 8A. FIG. 8B is a waveform diagram of the first oscillation light L1 emitted from the light source device 1 according to the third embodiment. The horizontal axis indicates a time, and the vertical axis indicates peak power. The excitation light source 2 according to the third embodiment outputs the first oscillation light L1 of the first wavelength Al having peak power P1 per above-described time interval Δt′. That is, thus, the light source device 1 according to the third embodiment outputs the first oscillation light L1 of the first wavelength λ1 as a pulse wave similar to the second oscillation light L2.

FIG. 8C is a waveform diagram of the second oscillation light L2 emitted from the light source device. The horizontal axis indicates a time, and the vertical axis indicates peak power. The light source device 1 outputs the second oscillation light L2 having peak power P2 per time interval λt.

The pulse interval (time interval Δt′) of the first oscillation light L1 is determined on the basis of a pulse interval of the driving current to be injected into the active layer 23. On the other hand, the pulse interval (time interval Δt) of the second oscillation light L2 is determined on the basis of the material and the thicknesses of the laser medium 3 and the saturable absorber 4, the reflectances of the first to fourth reflection layers R1 to R4, the driving current to be injected into the active layer 23, and the like.

The second driving current 12 may be also applied as the pulse current similarly to FIG. 8A. Consequently, the pulse interval of the second oscillation light L2 can be also controlled on the basis of the pulse interval of the second driving current 12 in addition to the above condition.

As described above, the light source device 1 according to the third embodiment can convert the first oscillation light L1 of the third wavelength λ3 into pulse light of an arbitrary pulse interval. Consequently, it is possible to switch and emit pulse light of different wavelengths by the light source device 1, and use the pulse light emitted from the light source device 1 as, for example, a light emission signal for ranging.

### Fourth Embodiment

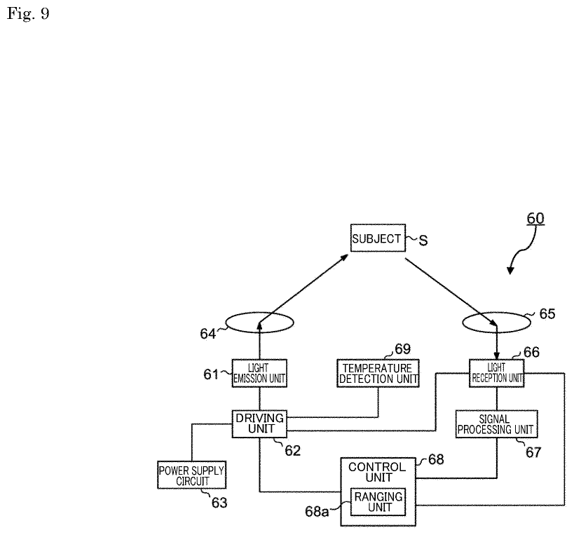

The light source device 1 according to the present disclosure can be applied to, for example, a ranging device. FIG. 9 illustrates a configuration example of a ranging device 60 as an implementation example of the light source device 1 according to the fourth embodiment. The ranging device 60 includes a light emission unit 61, a driving unit 62, a power supply circuit 63, a light emission side optical system 64, a light reception side optical system 65, a light reception unit 66, a signal processing unit 67, a control unit 68, and a temperature detection unit 69.

The light emission unit 61 includes the light source device 1 as a light source, and the light emission unit 61 may include a plurality of the light source devices 1 or may include the light source devices 1 aligned in, for example, a predetermined form such as a matrix pattern.

The driving unit 62 includes the power supply circuit 63 for driving the light emission unit 61. The power supply circuit 63 generates a power supply current of the driving unit 62 based on, for example, an input current from an unillustrated battery or the like provided to the ranging device 60. The driving unit 62 supplies a driving current to the active layer 23 of the light source device 1 disposed in the light emission unit 61 based on the power supply current.

Furthermore, the driving unit 62 imports from the light emission unit 61 a light emission signal indicating light emission of the light source device 1. The light emission signal is supplied to a ranging unit (distance measurement unit) 68a of the control unit 68. The light emission signal may be directly supplied to the ranging unit 68a, or may be supplied to the ranging unit 68a via the light reception unit 66.

The driving unit 62 may change the driving current to be supplied to the active layer 23 according to a distance to a ranging target (a subject S in FIG. 9).

Light emitted from the light emission unit 61 is radiated to the subject (target) S that is a ranging target through the light emission side optical system 64. Furthermore, light radiated in this way and reflected from the subject S enters the light reception surface of the light reception unit 66 through the light reception side optical system 65.

The light reception unit 66 is a light reception element such as a Charge Coupled Device (CCD) sensor or a Complementary Metal Oxide Semiconductor (CMOS) sensor, and receives light that is reflected from the subject S and enters through the light reception side optical system 65 as described above, converts the light into an electrical signal, and outputs the electrical signal.

The light reception unit 66 executes Correlated Double Sampling (CDS) processing, Automatic Gain Control (AGC) processing, or the like for the electrical signal obtained by photoelectric conversion of received light, and further performs Analog/Digital (A/D) conversion processing. Furthermore, the light reception unit 66 outputs a signal (light reception signal) as digital data to the signal processing unit 67 at a subsequent stage.

Furthermore, the light reception unit 66 according to the present example outputs a frame synchronizing signal Fs to the driving unit 62. Consequently, the driving unit 62 can cause the light source device 1 in the light emission unit 61 to emit light at a timing matching the frame period of the light reception unit 66.

The signal processing unit 67 is configured as a signal processing processor by, for example, a Digital Signal Processor (DSP). The signal processing unit 67 performs various types of signal processing on a light reception signal input from the light reception unit 66.

The control unit 68 includes a microcomputer including, for example, a Central Processing Unit (CPU), a Read Only Memory (ROM), and a Random Access Memory (RAM) or an information processing device such as a DSP, and controls the driving unit 62 for controlling a light emission operation of the light emission unit 61 and performs control related to a light reception operation of the light reception unit 66.

The control unit 68 has a function as the ranging unit 68a. The ranging unit 68a measures a distance to the subject S based on the light reception signal subjected to signal processing by the signal processing unit 67, and the light emission signal of the light source device 1 supplied from the driving unit 62. The ranging unit 68a according to the present example measures a distance to each part of the subject S to make it possible to specify the three-dimensional shape of the subject S.

The control unit 68 may notify the driving unit 62 of the distance to the subject S every time the ranging unit 68a measures the distance to the subject S.

The temperature detection unit 69 detects a temperature of the light emission unit 61. The temperature detection unit 69 may be configured to detect a temperature by using, for example, a diode.

In the present example, information about the temperature detected by the temperature detection unit 69 is supplied to the driving unit 62, so that the driving unit 62 can drive the light emission unit 61 based on information about the temperature.

As a ranging method of the ranging device 60, a ranging method such as a Structured Light (STL) method or a Time of Flight (ToF) method can be adopted.

When the STL method is adopted, for example, an Infrared (IR) light reception unit according to a global shutter method is used as the light reception unit 66.

Furthermore, in the case of the STL method, the ranging unit 68a controls the driving unit 62 to cause the light emission unit 61 to emit pattern light, detects pattern distortion for an image signal obtained through the signal processing unit 67, and calculates a distance based on the pattern distortion.

On the other hand, the ToF method is a method for measuring a distance to a target by detecting a time of flight (time difference) of light that is emitted from the light emission unit 61 and is reflected by the target to reach the light reception unit 66.

In a case where a so-called direct ToF (dToF) method is adopted as the ToF method, a Single Photon Avalanche Diode (SPAD) is used as the light reception unit 66, and the light emission unit 61 performs pulse driving. In this case, the ranging unit 68a calculates a time difference from emission to reception of light that is emitted from the light emission unit 61 and is received by the light reception unit 66, based on a signal input via the signal processing unit 67, and calculates a distance to each part of the subject S based on the time difference and the speed of light.

Note that, in a case where a so-called indirect ToF (iToF) method (phase difference method) is adopted as the ToF method, for example, a light reception unit that can receive IR is used as the light reception unit 66.

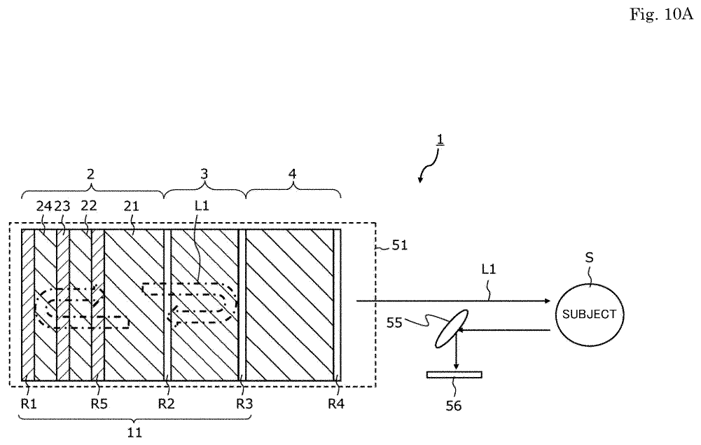

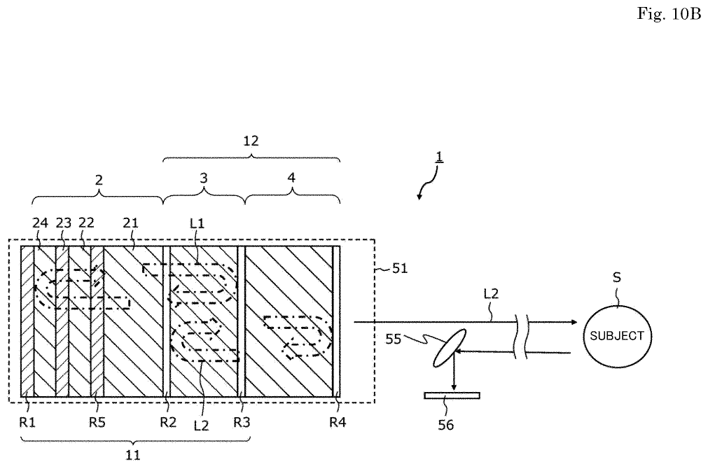

At a time of ranging of the ranging device 60, laser light to be emitted to the subject S may be switched according to the distance to the subject S. FIGS. 10A and 10B are diagrams illustrating an example where the light source device 1 in the ranging device 60 emits laser light to the subject S.

The control unit 68 notifies the driving unit 62 of the distance to the subject S every time the ranging unit 68a measures the distance to the subject S. When the subject S is at a close distance from the ranging device 60, peak power of laser light is desirably low.

FIG. 10A is a diagram illustrating an emitting operation of laser light of the light source device 1 in a case where the subject S is at a close distance from the ranging device 60. In FIG. 10A, the driving unit 62 injects the first driving current I1 into the active layer 23. Thus, the active layer 23 emits the first oscillation light L1 of the third wavelength λ3. The first oscillation light L1 of the third wavelength λ3 transmits through the third reflection layer R3, and therefore the laser medium 3 does not excite the second oscillation light L2. As a result, the light source device 1 emits to the subject S the first oscillation light L1 having relatively low peak power. The first oscillation light L1 radiated to the subject S is reflected by the subject S and received by the light reception unit 66, and the ranging unit 68a performs distance measurement on the close distance. The first reflection light L1 in this case has low peak power and does not reach far, and therefore is used for measuring the close distance.

On the other hand, when the subject S is at a remote distance from the ranging device 60, peak power of laser light is desirably high. FIG. 10B is a diagram illustrating an emitting operation of laser light of the light source device 1 in a case where the subject S is at a remote distance from the ranging device 60. In FIG. 10B, the driving unit 62 injects the second driving current 12 into the active layer 23. Thus, the active layer 23 emits the first oscillation light L1 of the fourth wavelength λ4. The excitation light L2 of the fourth wavelength λ4 is repeatedly reflected between the first reflection layer R1 and the third reflection layer R3, the first reflection light L1 of the sufficient amount is absorbed by the laser medium 3, and therefore the laser medium 3 excites the second oscillation light L2. The second oscillation light L2 is repeatedly reflected between the second reflection layer R2 and the fourth reflection layer R4, and, at a stage at which the saturable absorber 4 absorbs the second oscillation light L2 of a sufficient amount, the light source device 1 emits to the subject S the second oscillation light L2 of high peak power. The second oscillation light L2 is used for distance measurement of a remote distance.

The driving unit 62 may switch the driving current to be injected into the active layer 23 based on a ranging result of the ranging device 60. Consequently, the light source device 1 can emit oscillation light of optimal peak power according to the distance to the subject S.

As described above, the ranging device 60 according to the fourth embodiment can switch laser light to emit according to the distance to the subject S using one of the light source devices 1 according to the first to third embodiments. It is possible to emit laser light of high peak power to the subject S at a remote distance, and emit laser light of lower peak power taking laser safety into account for the subject S at the close distance, that is, separately use laser light depending on a situation.

### Exemplary Application to Moving Body

The technology of the present disclosure (the present technology) can be applied to various products. For example, the technique according to the present disclosure may be implemented as a device equipped in any type of moving body such as an automobile, an electric vehicle, a hybrid electric vehicle, a motorcycle, a bicycle, a personal mobility device, an airplane, a drone, a ship, and a robot.

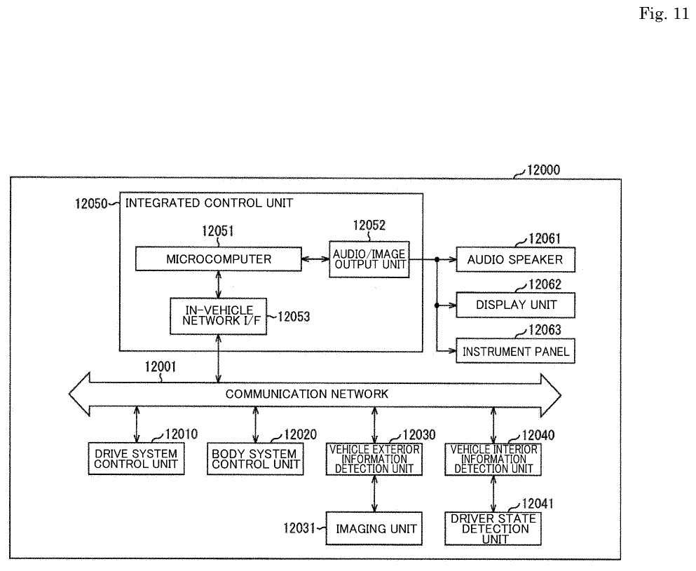

FIG. 11 is a block diagram illustrating a schematic configuration example of a vehicle control system that is an example of a moving body control system to which the technique according to the present disclosure is applicable.

A vehicle control system 12000 includes a plurality of electronic control units connected thereto via a communication network 12001. In the example illustrated in FIG. 11, the vehicle control system 12000 includes a drive system control unit 12010, a body system control unit 12020, a vehicle exterior information detection unit 12030, a vehicle interior information detection unit 12040, and an integrated control unit 12050. Furthermore, as a functional configuration of the integrated control unit 12050, a microcomputer 12051, an audio/image output unit 12052, and an in-vehicle network interface (I/F) 12053 are illustrated.

The drive system control unit 12010 controls an operation of an apparatus related to a drive system of a vehicle according to various programs. For example, the drive system control unit 12010 functions as a driving force generation device for generating a driving force of a vehicle such as an internal combustion engine or a driving motor, a driving force transmission mechanism for transmitting a driving force to wheels, a steering mechanism for adjusting a turning angle of a vehicle, and a control device such as a braking apparatus that generates a braking force of a vehicle.

The body system control unit 12020 controls operations of various devices equipped to the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, the body system control unit 12020 may receive input of radio waves transmitted from a portable device that substitutes for a key or signals of various switches. The body system control unit 12020 receives inputs of the radio waves or signals and controls a door lock device, a power window device, and a lamp of the vehicle.

The vehicle exterior information detection unit 12030 detects information on the outside of the vehicle having the vehicle control system 12000 mounted thereon. For example, the vehicle exterior information detection unit 12030 is connected with an imaging unit 12031. The vehicle exterior information detection unit 12030 causes the imaging unit 12031 to capture an image of the outside of the vehicle and receives the captured image. The vehicle exterior information detection unit 12030 may perform object detection processing or distance detection processing for peoples, cars, obstacles, signs, and letters on the road based on the received image.

The imaging unit 12031 is an optical sensor that receives light and outputs an electrical signal according to the light reception amount of this light. The imaging unit 12031 can also output the electrical signal as an image or ranging information. Furthermore, the light received by the imaging unit 12031 may be visible light or invisible light such as infrared light.

The vehicle interior information detection unit 12040 detects information on the inside of the vehicle. For example, the vehicle interior information detection unit 12040 is connected with a driver state detection unit 12041 that detects a driver's state. The driver state detection unit 12041 includes, for example, a camera that captures an image of a driver, and the vehicle interior information detection unit 12040 may calculate a degree of fatigue or a degree of concentration of the driver or may determine whether or not the driver is dozing on the basis of detection information input from the driver state detection unit 12041.

The microcomputer 12051 can calculate a control target value of the driving force generation device, the steering mechanism, or the braking device based on the information on the outside or the inside of the vehicle acquired by the vehicle exterior information detection unit 12030 or the vehicle interior information detection unit 12040 and output a control command to the drive system control unit 12010. For example, the microcomputer 12051 can perform cooperative control for the purpose of implementing functions of an Advanced Driver Assistance System (ADAS) including collision avoidance or impact mitigation of a vehicle, following traveling based on an inter-vehicle distance, vehicle speed maintenance driving, vehicle collision warning, vehicle lane deviation warning, or the like.

Furthermore, the microcomputer 12051 can perform cooperative control for the purpose of automated driving or the like of performing autonomous travel without depending on operations of the driver, by controlling the driving force generation device, the steering mechanism, the braking device, or the like based on information on the surroundings of the vehicle acquired by the vehicle exterior information detection unit 12030 or the vehicle interior information detection unit 12040.

Furthermore, the microcomputer 12051 can output a control command to the body system control unit 12020 based on the information on the outside acquired by the vehicle exterior information detection unit 12030. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The audio/image output unit 12052 transmits an output signal of at least one of an audio and an image to an output device capable of visually or audibly notifying a passenger or the outside of the vehicle of information. In the example in FIG. 11, an audio speaker 12061, a display unit 12062, and an instrument panel 12063 are exemplified as the output device. The display unit 12062 may include, for example, at least one of an on-board display and a head-up display.

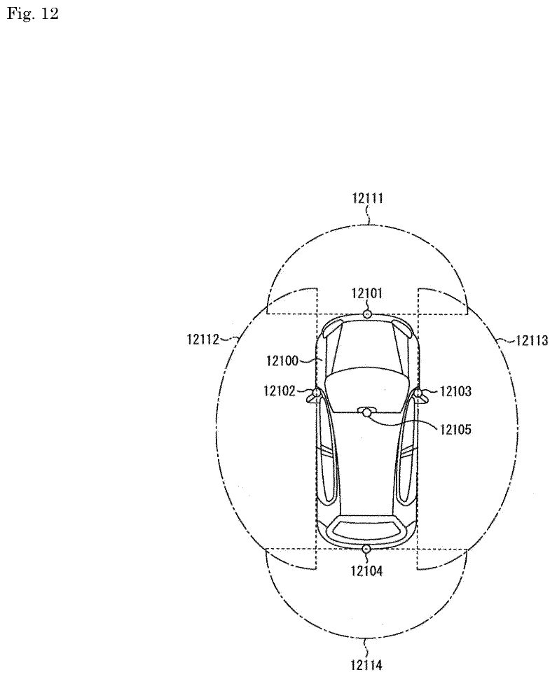

FIG. 12 is a diagram illustrating an example of the installation position of the imaging unit 12031.

In FIG. 12, a vehicle 12100 includes imaging units 12101, 12102, 12103, 12104, and 12105 as the imaging unit 12031.

The imaging units 12101, 12102, 12103, 12104, and 12105 are provided at positions such as a front nose, side view mirrors, a rear bumper, a back door, and an upper portion of a windshield in a vehicle interior of the vehicle 12100, for example. The imaging unit 12101 equipped to the front nose and the imaging unit 12105 equipped to the upper portion of the windshield in the vehicle interior mainly acquire images of the front of the vehicle 12100. The imaging units 12102 and 12103 equipped to the side-view mirrors mainly acquire images of a lateral side of the vehicle 12100.

The imaging unit 12104 equipped to the rear bumper or the back door mainly acquires images of the rear of the vehicle 12100. Images of the front acquired by the imaging units 12101 and 12105 are mainly used for detection of preceding vehicles, pedestrians, obstacles, traffic lights, traffic signs, lanes, and the like.

Note that FIG. 12 illustrates an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side view mirrors, and an imaging range 12114 indicates the imaging range of the imaging unit 12104 provided at the rear bumper or the back door. For example, by superimposing image data captured by the imaging units 12101 to 12104, it is possible to obtain a bird's-eye view image viewed from the upper side of the vehicle 12100.

At least one of the imaging units 12101 to 12104 may have a function for acquiring distance information. For example, at least one of the imaging units 12101 to 12104 may be a stereo camera including a plurality of imaging elements or may be an imaging element that has pixels for phase difference detection.

For example, the microcomputer 12051 can extract, particularly, the closest three-dimensional object that is on a traveling path of the vehicle 12100 and that travels at a predetermined speed (e.g., 0 km/h or higher) in the substantially same direction as that of the vehicle 12100, as a preceding vehicle by obtaining a distance to each three-dimensional object in the imaging ranges 12111 to 12114 and a temporal change of this distance (a relative speed with respect to the vehicle 12100) based on the distance information obtained from the imaging units 12101 to 12104. Furthermore, the microcomputer 12051 can set an inter-vehicle distance that needs to be secured in advance in front of the preceding vehicle and can perform automated brake control (also including following stop control) or automated acceleration control (also including following start control). In this way, cooperative control can be performed for the purpose of automated traveling or the like of performing automated traveling without the operations of the driver.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104, and can use the three-dimensional data to perform automated avoidance of obstacles. For example, the microcomputer 12051 differentiates surrounding obstacles of the vehicle 12100 into obstacles that can be viewed by the driver of the vehicle 12100 and obstacles that are difficult to view. Furthermore, the microcomputer 12051 determines a collision risk indicating the degree of risk of collision with each obstacle, and when the collision risk is a setting value or more and there is a possibility of collision, outputs an alarm to the driver through the audio speaker 12061 or the display unit 12062, or performs forced deceleration or avoidance steering through the drive system control unit 12010, so that it is possible to perform driving support for collision avoidance.

At least one of the imaging units 12101 to 12104 may be an infrared camera that detects infrared rays. For example, the microcomputer 12051 can recognize a pedestrian by determining whether or not there is a pedestrian in the captured images of the imaging units 12101 to 12104. Such pedestrian recognition is performed by, for example, a procedure of extracting feature points in the captured images of the imaging units 12101 to 12104 that are infrared cameras, and a procedure of performing pattern matching processing on a series of feature points indicating an outline of an object and determining whether or not the object is a pedestrian. When the microcomputer 12051 determines that there is a pedestrian in the captured images of the imaging units 12101 to 12104 and recognizes the pedestrian, the audio/image output unit 12052 controls the display unit 12062 so as to superimpose a square contour line for emphasis on the recognized pedestrian to display. Furthermore, the audio/image output unit 12052 may control the display unit 12062 so as to display an icon indicating a pedestrian or the like at a desired position.

An example of the vehicle control system to which the technology according to the present disclosure can be applied has been described above. The technology according to the present disclosure can be applied to, for example, each imaging unit 12031 among the components described above. More specifically, the light source device 1 according to the present disclosure is preferably provided together with the imaging unit 12031. By applying the technique according to the present disclosure to the imaging unit 12031, it is possible to vary peak power of laser light, and enhance functionality and safety of the vehicle control system.

Note that the present technique can also take on the following configurations.
(1) A light source device includes:
a laminated semiconductor layer that includes an active layer that emits light of a first wavelength that is a wavelength that changes according to a driving condition, and a first reflection layer that is used for the first wavelength:
a second reflection layer that is disposed on a first surface facing a light emission surface of the laminated semiconductor layer, and is used for a second wavelength;
a third reflection layer that is disposed on a second surface disposed closer to a rear side of an optical axis than the first surface, and is used for the first wavelength; a laser medium that is disposed between the second reflection layer and the third reflection layer;
a fourth reflection layer that is disposed on the second surface or is disposed closer to the rear side of the optical axis than the second surface and is used for the second wavelength; and
a first resonator that resonates the light of the first wavelength between the first reflection layer and the third reflection layer, and
an optical axis of the laminated semiconductor layer and an optical axis of the laser medium are arranged uniaxially.
(2) In the light source device described in (1), the driving condition includes at least one of a driving current to be injected into the active layer, and a temperature of the active layer.
(3) In the light source device described in (2), the active layer emits light of one of at least two types of the first wavelengths whose wavelengths are respectively different according to the driving current, and
the third reflection layer has respectively different reflectances for the at least two types of first wavelengths.
(4) In the light source device described in (2) or (3),
the active layer emits the light of the longer first wavelength as the driving current is larger, and
the third reflection layer makes the reflectance higher as the first wavelength is longer.
(5) In the light source device described in (2) or (3),
the active layer emits the light of the longer first wavelength as the driving current is larger, and
the third reflection layer makes the reflectance lower as the first wavelength is longer.
(6) In the light source device described in (2) or (3),
the first wavelength includes a third wavelength that is emitted when a first driving current is caused to flow to the active layer, and a fourth wavelength that is emitted when a second driving current is caused to flow to the active layer, and
the third reflection layer has respectively different reflectances for the third wavelength and the fourth wavelength.
(7) In the light source device described in (6),
the third reflection layer has the higher reflectance for the fourth wavelength than the reflectance for the third wavelength, and
the laser medium does not excite the second wavelength for the third wavelength, and excites the second wavelength for the fourth wavelength.
(8) In the light source device described in (6),
the third reflection layer has the lower reflectance for the fourth wavelength than the reflectance for the third wavelength, and
the laser medium does not excite the second wavelength for the fourth wavelength, and excites the second wavelength for the third wavelength.
(9) In the light source device described in any one of (6) to (8),
the first driving current is smaller than the second driving current, and
the third wavelength is shorter than the fourth wavelength.
(10) In the light source device described in any one of (1) to (9),
the laminated semiconductor layer includes a plurality of first regions that emit light of the respectively different first wavelengths, and
the third reflection layer includes a plurality of the second regions that are provided to meet the plurality of first regions, and have respectively different reflectances for the first wavelengths.
(11) In the light source device described in any one of (6) to (9),
the laminated semiconductor layer includes a plurality of first regions that emit light of the third wavelength or the fourth wavelength, and
the third reflection layer includes a plurality of second regions that are provided to meet the plurality of the first regions, and have respectively different reflectances for the third wavelength and the fourth wavelength.
(12) In the light source device described in any one of (1) to (9), the laminated semiconductor layer intermittently emits the light of the first wavelength.
(13) The light source device described in any one of (1) to (12) further includes a second resonator that resonates light of the second wavelength between the second reflection layer and the fourth reflection layer.
(14) The light source device described in any one of (1) to (13) further includes a saturable absorber that includes the fourth reflection layer, and
the optical axis of the laminated semiconductor layer, the optical axis of the laser medium, and an optical axis of the saturable absorber are arranged uniaxially.
(15) In the light source device described in (14), the light of the second wavelength has peak power higher than peak power of the light of the first wavelength.
(16) In the light source device described in (14) or (15), the fourth reflection layer emits Q switch pulse wave light of the second wavelength.
(17) A ranging device includes:
a light source device that can switch a wavelength and emit light;
a light reception unit; and
a distance measurement unit that, when a light emission signal of the light source device is reflected by a target and received by the light reception unit, measures a distance to the target based on the light emission signal and a light reception signal of the light reception unit,
the light source device includes
a laminated semiconductor layer that includes an active layer that emits light of a first wavelength that is a wavelength that changes according to a driving condition, and a first reflection layer that is used for the first wavelength,
a second reflection layer that is disposed on a first surface facing a light emission surface of the laminated semiconductor layer, and is used for a second wavelength,
a third reflection layer that is disposed on a second surface disposed closer to a rear side of an optical axis than the first surface, and is used for the first wavelength, a laser medium that is disposed between the second reflection layer and the third reflection layer,
a fourth reflection layer that is disposed on the second surface or is disposed closer to the rear side of the optical axis than the second surface and is used for the second wavelength,
a first resonator that resonates the light of the first wavelength between the first reflection layer and the third reflection layer, and
a second resonator that resonates light of the second wavelength between the second reflection layer and the fourth reflection layer, and
an optical axis of the laminated semiconductor layer and an optical axis of the laser medium are arranged uniaxially.
(18) The ranging device described in (17) further includes a driving unit that controls the driving condition according to the distance to the target.
(19) In the ranging device described in (18), the driving unit switches and controls peak power of the light emission signal emitted from the light source device according to the distance to the target.
(20) A ranging method includes
when a light emission signal of a light source device that can switch a wavelength and emit light is reflected by a target and received by a light reception unit, measuring a distance to the target based on the light emission signal and a light reception signal of the light reception unit,
the light source device is formed by laminating
a laminated semiconductor layer that includes an active layer that emits light of a first wavelength that is a wavelength that changes according to a driving condition, and a first reflection layer that is used for the first wavelength,
a second reflection layer that is disposed on a first surface facing a light emission surface of the laminated semiconductor layer, and is used for a second wavelength,
a third reflection layer that is disposed on a second surface disposed closer to a rear side of an optical axis than the first surface, and is used for the first wavelength,
a laser medium that is disposed between the second reflection layer and the third reflection layer,
a fourth reflection layer that is disposed on the second surface or is disposed closer to the rear side of the optical axis than the second surface and is used for the second wavelength,
a first resonator that resonates the light of the first wavelength between the first reflection layer and the third reflection layer, and
a second resonator that resonates light of the second wavelength between the second reflection layer and the fourth reflection layer, and
an optical axis of the laminated semiconductor layer and an optical axis of the laser medium are arranged uniaxially.

Aspects of the present disclosure are not limited to the aforementioned individual embodiments and include various modifications that those skilled in the art can achieve, and effects of the present disclosure are also not limited to the details described above. In other words, various additions, modifications, and partial deletion can be made without departing from the conceptual idea and the gist of the present disclosure that can be derived from the details defined in the claims and the equivalents thereof.

### REFERENCE SIGNS LIST

1 Light source device
2 Excitation light source
3 Laser medium
4 Saturable absorber
5 Support body
11 First resonator
12 Second resonator
21 Substrate
22, 24 Clad layer
23 Active layer
25 Contact layer
51 Mount member
52 Submount member
53a, 53b Wiring layer
54a, 54b Pin
55a, 55b Wire
56a, 56b Solder layer
57, 58 Conductive layer
59a, 59b Insulation layer
60 Ranging device
61 Light emission unit
62 Driving unit
63 Power supply circuit
64 Light emission side optical system
65 Light reception side optical system
66 Light reception unit
67 Signal processing unit
68 Control unit
68a Ranging unit
69 Temperature detection unit

1. A light source device comprising:
a laminated semiconductor layer that includes an active layer that emits light of a first wavelength that is a wavelength that changes according to a driving condition, and a first reflection layer that is used for the first wavelength;
a second reflection layer that is disposed on a first surface facing a light emission surface of the laminated semiconductor layer, and is used for a second wavelength;
a third reflection layer that is disposed on a second surface disposed closer to a rear side of an optical axis than the first surface, and is used for the first wavelength;
a laser medium that is disposed between the second reflection layer and the third reflection layer;
a fourth reflection layer that is disposed on the second surface or is disposed closer to the rear side of the optical axis than the second surface and is used for the second wavelength; and
a first resonator that resonates the light of the first wavelength between the first reflection layer and the third reflection layer,
wherein an optical axis of the laminated semiconductor layer and an optical axis of the laser medium are arranged uniaxially.

2. The light source device according to claim 1, wherein the driving condition includes at least one of a driving current to be injected into the active layer, and a temperature of the active layer.

3. The light source device according to claim 2, wherein
the active layer emits light of one of at least two types of the first wavelengths whose wavelengths are respectively different according to the driving current, and
the third reflection layer has respectively different reflectances for the at least two types of first wavelengths.

4. The light source device according to claim 2, wherein
the active layer emits the light of the longer first wavelength as the driving current is larger, and
the third reflection layer makes the reflectance higher as the first wavelength is longer.

5. The light source device according to claim 2, wherein
the active layer emits the light of the longer first wavelength as the driving current is larger, and
the third reflection layer makes the reflectance lower as the first wavelength is longer.

6. The light source device according to claim 2, wherein
the first wavelength includes a third wavelength that is emitted when a first driving current is caused to flow to the active layer, and a fourth wavelength that is emitted when a second driving current is caused to flow to the active layer, and
the third reflection layer has respectively different reflectances for the third wavelength and the fourth wavelength.

7. The light source device according to claim 6, wherein
the third reflection layer has the higher reflectance for the fourth wavelength than the reflectance for the third wavelength, and
the laser medium does not excite the second wavelength for the third wavelength, and excites the second wavelength for the fourth wavelength.

8. The light source device according to claim 6, wherein
the third reflection layer has the lower reflectance for the fourth wavelength than the reflectance for the third wavelength, and
the laser medium does not excite the second wavelength for the fourth wavelength, and excites the second wavelength for the third wavelength.

9. The light source device according to claim 6, wherein
the first driving current is smaller than the second driving current, and
the third wavelength is shorter than the fourth wavelength.

10. The light source device according to claim 1, wherein
the laminated semiconductor layer includes a plurality of first regions that emit light of the respectively different first wavelengths, and
the third reflection layer includes a plurality of second regions that are provided to meet the plurality of the first regions, and have respectively different reflectances for the first wavelengths.

11. The light source device according to claim 6, wherein
the laminated semiconductor layer includes a plurality of first regions that emit light of the third wavelength or the fourth wavelength, and
the third reflection layer includes a plurality of second regions that are provided to meet the plurality of the first regions, and have respectively different reflectances for the third wavelength and the fourth wavelength.

12. The light source device according to claim 1, wherein the laminated semiconductor layer intermittently emits the light of the first wavelength.

13. The light source device according to claim 1, further comprising a second resonator that resonates light of the second wavelength between the second reflection layer and the fourth reflection layer.

14. The light source device according to claim 13, further comprising a saturable absorber that includes the fourth reflection layer,
wherein the optical axis of the laminated semiconductor layer, the optical axis of the laser medium, and an optical axis of the saturable absorber are arranged uniaxially.

15. The light source device according to claim 14, wherein the light of the second wavelength has peak power higher than peak power of the light of the first wavelength.

16. The light source device according to claim 14, wherein the fourth reflection layer emits Q switch pulse wave light of the second wavelength.

17. A ranging device comprising:
a light source device that can switch a wavelength and emit light;
a light reception unit; and
a distance measurement unit that, when a light emission signal of the light source device is reflected by a target and received by the light reception unit, measures a distance to the target based on the light emission signal and a light reception signal of the light reception unit, wherein
the light source device includes
a laminated semiconductor layer that includes an active layer that emits light of a first wavelength that is a wavelength that changes according to a driving condition, and a first reflection layer that is used for the first wavelength,
a second reflection layer that is disposed on a first surface facing a light emission surface of the laminated semiconductor layer, and is used for a second wavelength,
a third reflection layer that is disposed on a second surface disposed closer to a rear side of an optical axis than the first surface, and is used for the first wavelength,
a laser medium that is disposed between the second reflection layer and the third reflection layer,
a fourth reflection layer that is disposed on the second surface or is disposed closer to the rear side of the optical axis than the second surface and is used for the second wavelength,
a first resonator that resonates the light of the first wavelength between the first reflection layer and the third reflection layer, and
a second resonator that resonates light of the second wavelength between the second reflection layer and the fourth reflection layer, and
an optical axis of the laminated semiconductor layer and an optical axis of the laser medium are arranged uniaxially.

18. The ranging device to claim 17, further comprising a driving unit that controls the driving condition according to the distance to the target.

19. The ranging device to claim 18, wherein the driving unit switches and controls peak power of the light emission signal emitted from the light source device according to the distance to the target.

20. A ranging method comprising
when a light emission signal of a light source device that can switch a wavelength and emit light is reflected by a target and received by a light reception unit, measuring a distance to the target based on the light emission signal and a light reception signal of the light reception unit, wherein
the light source device is formed by laminating
a laminated semiconductor layer that includes an active layer that emits light of a first wavelength that is a wavelength that changes according to a driving condition, and a first reflection layer that is used for the first wavelength,
a second reflection layer that is disposed on a first surface facing a light emission surface of the laminated semiconductor layer, and is used for a second wavelength,
a third reflection layer that is disposed on a second surface disposed closer to a rear side of an optical axis than the first surface, and is used for the first wavelength, a laser medium that is disposed between the second reflection layer and the third reflection layer,
a fourth reflection layer that is disposed on the second surface or is disposed closer to the rear side of the optical axis than the second surface and is used for the second wavelength,
a first resonator that resonates the light of the first wavelength between the first reflection layer and the third reflection layer, and
a second resonator that resonates light of the second wavelength between the second reflection layer and the fourth reflection layer, and
an optical axis of the laminated semiconductor layer and an optical axis of the laser medium are arranged uniaxially.
